(19) United States
(12) Patent Application Publication
(10) Pub. No.: US 2002/0179921 A1
(43) Pub. Date: Dec. 5, 2002

(54) Compliant hermetic package

(76) Inventor: Michael B. Cohn, Berkeley, CA (US)

Correspondence Address: Wallace Tang, MicroAssembly Technologies, Inc., Suite 109, 3065 Richmond Parkway, Richmond, CA, 94806, US

(21) Appl. No.: 10/162,515

(22) Filed: Jun. 3, 2002

Related U.S. Application Data
(60) Provisional application No. 60/295,375, filed on Jun. 2, 2001.

(51) Int. Cl. H01L 33/00

(52) U.S. Cl. 257/99

(57) ABSTRACT

The present invention provides a compliant seal, particularly for bonding substrates having different thermal expansion coefficients. This invention is also applicable for attaching substrates requiring a significant gap between said substrates.

This application is based on provisional patent application No. 60/295,375 with a filing date of Jun. 2, 2001 entitled “Wafer-level hermetic package using microfabricated bellows”.

### STATEMENT REGARDING FEDERALLY SPONSORED RESEARCH OR DEVELOPMENT

None.

### TECHNICAL FIELD OF THE INVENTION

The present invention relates to providing compliant sealing and interconnecting means for packaging, integration and assembly of mixed technologies. This is particularly important for sealing, assembly, integration, and packaging of different substrates.

### BACKGROUND OF THE INVENTION

Microelectromechanical systems (“MBMS”) have been utilized for many applications, including but not limited to accelerometers, gyroscopes, pressure sensors, tunable lasers, fiber optic components, optical switches, optical attenuators, planar waveguides, optical alignment fixtures, wireless components, RF MEMS switches, variable capacitors, biosensors, or microfluidic channels. Many of these and other MEMS devices require the integration of multiple substrates. For example, MEMS tunable laser components may require the integration of III-V semiconductor lasers with polysilicon actuators and various fiber alignment devices. A second example would be the integration of polysilicon RF MEMS devices with III-V power amplifiers for high-performance low-power-consumption load-matched, power amplifier modules. A third example would be to hermetically seal components requiring high reliability, but yet minimize component packaging size by bonding said components directly on a substrate, and to provide a hermetic seal between said component and said substrate. A fourth example would be to provide a transparent window for 3-D fiber optic switches.

A perennial problem has been that stresses—originating from thermal expansion, thermal gradients, the device's mounting process, or other causes—can cause seal failure or even complete or partial detachment of substrates from each other. For this reason, and also from other applications, including but not limited to applications that would benefit from having a significant gap between at least 2 substrates, including but not limited to those applications requiring significant gaps for optic design, the current invention provides compliant seal structures, or compliant structures for integration or assembly of different substrates.

A key consideration is that the thermal expansion coefficients of various semiconductor substrates, printed circuit boards, MCM substrates, and other interconnect substrates are different. The problem is further exacerbated by the trend toward larger chip sizes, in which the thermal expansion mismatch leads to even larger shear stresses. Several groups have demonstrated compliant interconnections, and miniature electroformed bellows are commercially available, however, compliant seals which are mass manufacturable on a planar paradigm would be highly desirable.

For compliant interconnections, microsprings and other compliant interconnection approaches have been demonstrated by various groups, including FormFactor, Inc., Tessera Inc. and Hitachi Inc. These compliant interconnect designs are typified by U.S. Pat. Nos. 4,893,172, 5,832,601, 6,184,053, 5,476,211, 6,049,976, 5,917,707, and 6,117,694, and Japanese Patent Nos. 121255 and 110441.

Large-Scale Manufacturability of Sealing Structures

While conventional hermetic sealing techniques are well-established, they require more costly packages, and complicates the packaging process. Conventional wafer bonding techniques such as anodic bonding and fusion bonding are also well-established means for sealing cavities, but they require very flat surfaces and often high temperatures. The use of surface micromachining to form a wide variety of compliant sealing structures would be particularly desirable from a cost and size perspective.

Available fabrication processes of such microstructures, however, often require at least two layers: a structural layer and a sacrificial layer. At this time, it is difficult to consider adding these additional materials, and the associated processing steps, to the already-complex process of fabricating IC or MEMS chips. One reason is that with each added step, such as etching or film deposition, there is the risk and potential to interact with structures or materials already on the wafer. Some of the embodiments of this invention provide for compliant sealing structures without the need for any additional layer to serve as a sacrificial layer.

### BRIEF SUMMARY OF THE INVENTION

With the present invention, compliant sealing structures are formed preferably lithographically by forming a conductive substantially-planar structure on a substrate such as a silicon wafer. The structure is preferably formed using electroplating and/or sputtering to deposit a metal such as nickel, gold, copper, tin, or some alloy or combination of these materials. Other techniques including but not limited to electroless plating, vapor deposition, and/or etching may also be used. Ultimately, a first end of each compliant structure ends up affixed to the bonding areas of one substrate, including but not limited to an IC, MEMS chip, or another substrate. A second end of the compliant structure ends up affixed to another substrate, including but not limited to an IC, MEMS chip, or another substrate. The invention includes but is not limited to:

1. A device with at least two substrates, wherein at least two substrates are mechanically attached to at least one compliant structure.

2. A method of assembly of at least two substrates with at least one compliant structure, wherein said at least one compliant structure seals at least one location between at least two substrates.

3. A device with at least two substrates, wherein at least two substrates are mechanically attached to at least one compliant structure, wherein said at least two substrates are bonded to each other with a bonding technique selected from the following list:

a. gold bump bonding,

b. gold bump bonding at room temperature

c. gold bump bonding near room temperature

d. bonding at room temperature

e. bonding near room temperature

f. solder bump bonding,

g. indium bump bonding,

h. polymer bump bonding,

i. bonding with gold on at least one bonding surface,

j. bonding with solder on at least one bonding surface,

k. bonding with indium on at least one bonding surface,

l. bonding with conductive polymer on at least one bonding surface,

m. bonding wherein at least one adhesive provides at least the majority of the bonding strength between said substrates,

n. bonding wherein at least one adhesive provides at least majority of the bonding strength between said substrates, and device hermeticity is improved from structures which assist in sealing including but not limited of structures which comprises at least one less-gas-permeable material from deposited layers, substrate, or combination including but not limited to silicon oxide, single crystal silicon, polysilicon, silicon nitride, gold, nickel, indium, titanium, tungsten, titanium nitride, solder, other ceramics, other metals, or any combination,

o. bonding wherein at least one adhesive provides at least the majority of the bonding strength between said substrates, and device hermeticity is improved from at least one knife-blade type seal, crush-gasket type seal or a combination which comprises at least one less-gas-permeable material from deposited layers, substrate, or combination including but not limited to silicon oxide, single crystal silicon, polysilicon, silicon nitride, gold, nickel, indium, titanium, tungsten, titanium nitride, solder, other ceramics, other metals, or any combination,

p. bonding wherein at least one adhesive provides at least the majority of the bonding strength between said substrates, and device hermeticity is improved by adding at least one less gas permeable material into the adhesive or add at least one less-gas-permeable material adjacent to the adhesive by depositing layers on one or more substrates, removing materials from one or more substrates, or any combination,

q. bonding wherein a solder bond provides the majority of the bonding strength between said substrates,

r. bonding wherein a gold thermal compression bond provides the majority of the bonding strength between said substrates,

s. bonding wherein a gold compression bond provides the majority of the bonding strength between said substrates,

t. bonding wherein the majority of the bonding strength between said substrates is provided from a bonding process involving the formation of at least one amalgam,

u. bonding wherein the majority of the bonding strength between said substrates is provided from a cold welding process,

v. any combination including at least one of the above bonding processes.

The compliant sealing structures should be sufficiently compliant to accommodate this deformation while remaining in the elastic range of stress (generally 0.2% for most metals), and without transmitting excessive force to the bonding areas on the substrates. The sealing structures, however, would preferably be no more compliant than necessary, in order to secure the substrates.

In a simpler embodiment, the compliant sealing structure and compliant electrical interconnects would be formed of at least one bondable metal, such as gold, eliminating the need for a separate metal or solder. Since the sealing structure is preferably electroplated, a seed layer is present underneath the sealing structure. This seed layer can generally be selectively etched, thus eliminating the need for a separate sacrificial layer. Thus certain embodiments of the current invention eliminate the need for an additional layer for a sacrificial layer.

This invention can be used to fabricate compliant sealing structures and compliant electrical connectors, or microelectromechanical systems (“MEMS”) devices including but not limited to spring, gyroscope, accelerometer, inductor, variable inductor, capacitor, variable capacitor, mirror, optical switch, optical attenuator, optical alignment fixture, antenna, RF switch, RF filter, laser, tunable laser, planar waveguide, hermetically-sealed ICs, hermetically sealed MEMS devices, or hermetically sealed optoelectronic devices.

### BRIEF DESCRIPTION OF THE SEVERAL OF THE DRAWINGS

FIG. 1. An illustration of a rectangular shaped compliant seal with rounded corners, 3, on seal substrate, 1.

FIG. 2 An illustration of a circular shaped compliant seal, 4, on seal substrate, 1.

FIG. 3 An illustration of a hexagon shaped compliant seal with rounded corners, 5, on seal substrate, 1.

FIG. 4 An illustration of a rectangular shaped compliant seal with rounded comers and vertical corrugation, 6, on seal substrate, 1, and attached to another substrate, 2, with bonding layer, 7.

FIG. 5 An illustration of the use of compliant electrical interconnects, 8, with compliant sealing structures, 5 (hexagon shape in this case), on seal substrate 1.

FIG. 6. Illustrations of bonding wherein at least one adhesive, 9, provides at least the majority of the bonding strength between said substrates, 1 and 2, and device hermeticity is improved from at least one knife-blade type seal, crush-gasket type seal or a combination, 11, using a less-gas-permeable material from deposited layers, substrate, or combination. FIG. 6A illustrates a knife-blade type seal, 11, with adhesive bonding using added deposited layers, additional layer, 10, and seal, 11. FIG. 6B illustrates a knife-blade type seal formed by etching substrate, 1, and bonded with adhesive, 9, and optionally, seal is improved using knife-edge type seal, 11. Optionally, adhesive can be replaced with other bonding means listed under this invention. Adhesive, 9, or other bonding materials would preferably be located at the etched cavities and/or on top of the knife-blade/crush gasket.

FIG. 7. An illustration of compliant sealing structures, 5 (hexagon shape), and devices of interest, 12, on the same substrate, 1, which is bonded to a substrate, 2, with no compliant sealing structures nor devices of interest.

FIG. 8. An illustration of compliant sealing structures, 5 (hexagon shape), on both substrates, 1 and 2, to be bonded together.

FIG. 9 An illustration of a polysilicon MEMS accelerometer device wherein polysilicon MEMS structure, 13, hexagon shape compliant sealing structures, 5, and compliant electrical interconnects, 8, share a common silicon dioxide sacrificial layer and common doped polysilicon structural layer on substrate, 1.

FIG. 10 An illustration of a silicon-on-insulator MEMS accelerometer device wherein single crystalline silicon MEMS structure, 14, hexagon shape compliant sealing structures, 5, and compliant electrical interconnects, 8, share a common silicon dioxide sacrificial layer and common single-crystalline silicon layer on substrate 1.

FIG. 11 An illustration of MEMS components on one substrate, 2, which is bonded to hexagon shape compliant sealing structures, 5, on seal substrate, 1. Optional metallization, 15, is for certain bonding processes, particularly metal-metal bonding processes, including but not limited gold bump, solder bump, indium bump, at room temperature, near room temperature or any process including any of these processes. For other substrate, 2, optional metallization, 15, hexagon shape in this case, would preferably be gold, noble metals, or metal with no or little surface oxides, but other metallization include but is not limited to copper, aluminum, barrier layers, titanium, adhesion layers, tungsten, or any combination. Bonding performance can be improved by using cleaning processes as listed in the fabrication processes.

FIG. 12 An illustration of MEMS components on one or both substrates to be bonded together (seal substrate, 1, in this case), and hexagon shape compliant sealing structures, 5, on one or both substrates, 1 and 2 (both in this case), to be bonded together.

### DETAIL DESCRIPTION OF THE INVENTION

Compliant Sealing Structure Designs

One or more compliant sealing structure(s) can be used to seal two or more substrates together. After sealing, optionally, at least one portion of at least one substrate can be removed by various means, including but not limited to mechanical abrasion, polishing, lapping, wet etching, dry etching, laser, chemical etching, ion milling, breaking apart at tethers or at areas designed for breaking, or any combination. In some cases which involve substantial removal of at least one substrate, the process has ‘effectively’ transferred devices from one substrate to the other.

Examples of sealed devices include one substrate having at least one device which is sealed with at least one separate substrate, wherein said substrates are sealed with at least one compliant sealing structure which relieves substantial stresses from thermal expansion and/or other causes. Said device may be selected from, but is not limited to, the following list:

a. Micromachined device

b. Microelectromechanical systems (MEMS) device

c. Integrated circuit

d. Device with at least one transistor

e. Optoelectronic device

f. Any combination of the above or other devices.

Compliant sealing structures include but are not limited to complete seal rings which along with said substrates completely enclose at least one volume of space, and at least one area of said seal rings is flexible enough to adequate relieve stress arising from thermal expansion and/or other causes. Flexibility can be from providing corrugation or thinned areas, narrow areas, or long aspect ratio designs in directions including but not limited to parallel, orthogonal, along, or other directions relatively to the plane of substrates. Additional flexibility can be provided by thinning at least one substrate at at least one area. At least one of said substrates would preferably be a wafer. For large volume production, two substrates would preferably be used, wherein both substrates would preferably be roughly the same size, and would preferably be wafers. The wafers would preferably contain many devices requiring sealing with said compliant sealing structures.

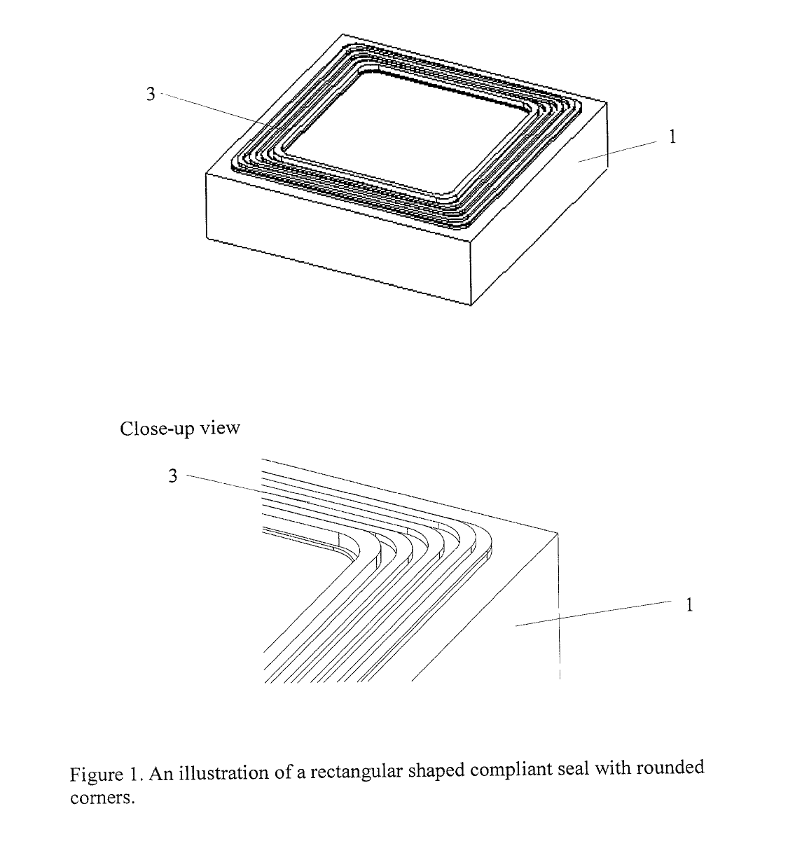

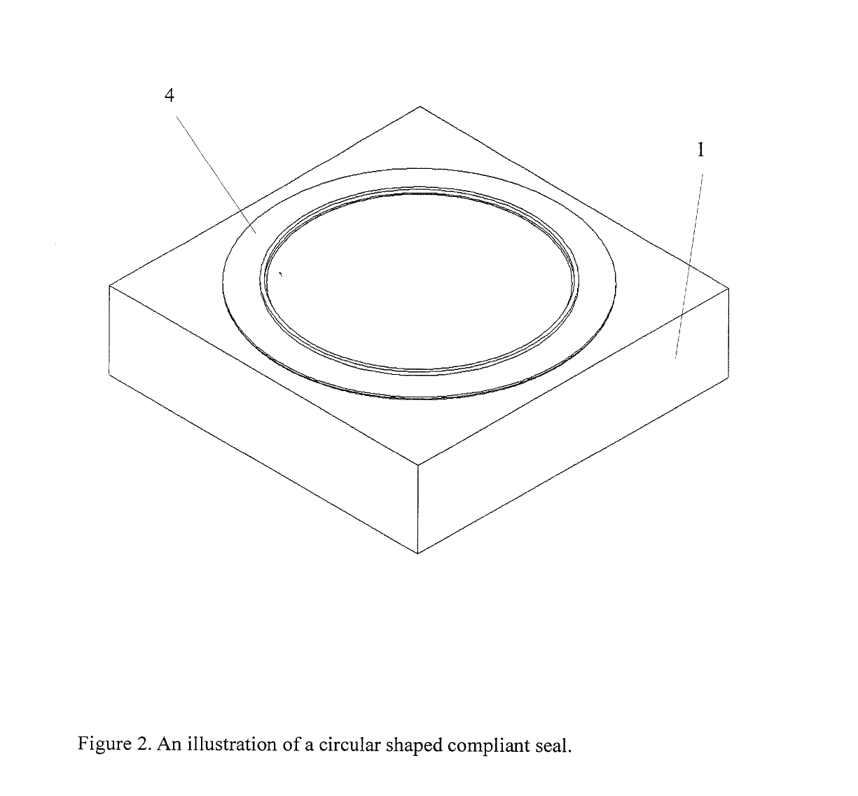

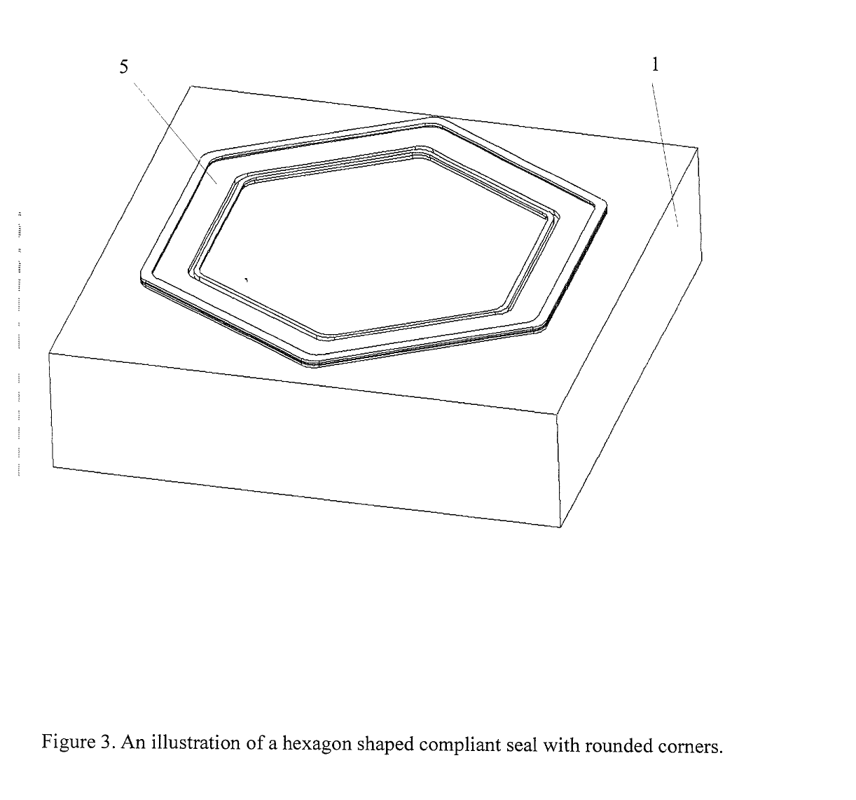

For improving seal reliability and performance, rounding the corners of sealing structures will be preferable. Even more preferable would be a round shaped seal. Other embodiments include but are not limited to a hexagon with rounded corners and a rectangle with rounded corners. For providing improved sealing performance, at least two seals can be provided concentric to each other. Improved hermeticity or vacuum sealing can be provided by adding getters in the sealed areas. Getters would preferably be at least one integrated getter formed using microfabrication processes, but getters can also be applied in liquid form or solid form in a package-at-a-time mode, or some other efficient manufacturing flow. More than one sealing structure may be used for sealing an area, which may include one or more devices. Additional bonded compliant and/or non-compliant structures, which do not provide sealing, can be added to provide additional bonding force to keep substrates together or for other purposes. FIG. 1 shows an illustration of a rectangular shaped compliant seal with rounded corners, 3, on seal substrate, 1. FIG. 2 shows an illustration of a circular shaped compliant seal, 4, on seal substrate, 1. FIG. 3 shows an illustration of a hexagon shaped compliant seal with rounded corners, 5 on seal substrate, 1.

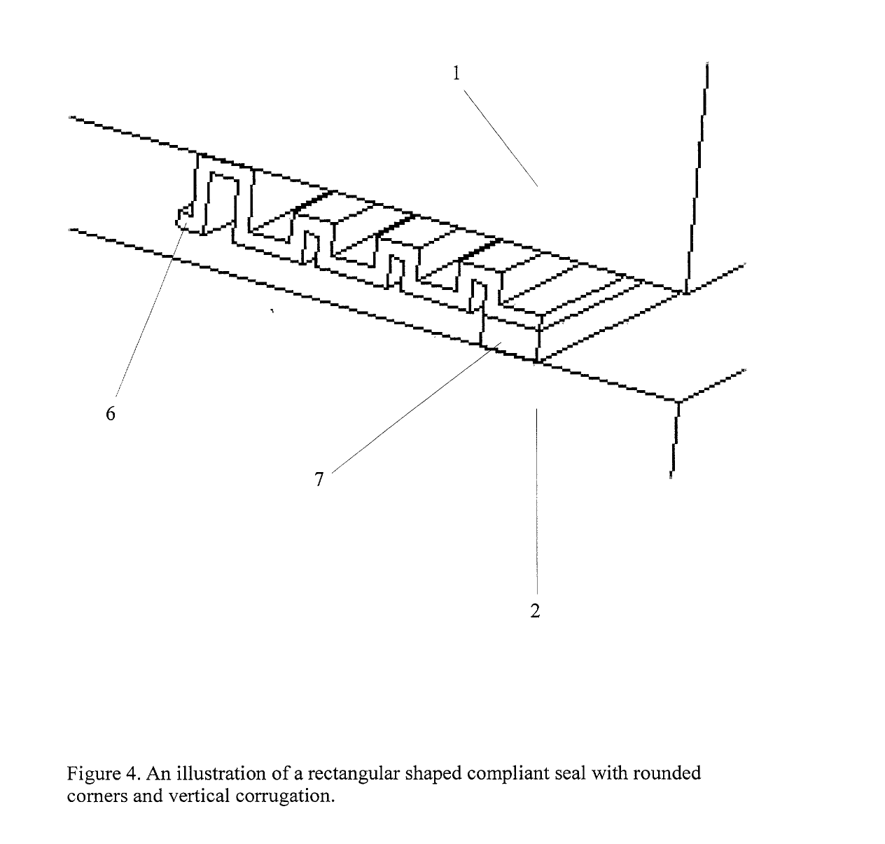

To improve seal reliability and performance, it is preferable to corrugated vertically and/or horizontally. By corrugating vertically, the vertical compliance would probably be better. FIG. 4 shows an illustration a rectangular shaped compliant seal with rounded corners and vertical corrugation, 6, on seal substrate, 1. Corrugation can be provided by various means, including lithographically patterning corrugation pattern and then etching on the substrate prior to depositing applicable layers of sealing structures, and corners can be rounded using various process, including but not limited to wet and dry/plasma etching. Compliant seal with corrugation, 6, is formed on sealing substrate, 1, and bonded to another substrate, 2, with bonding layer, 7.

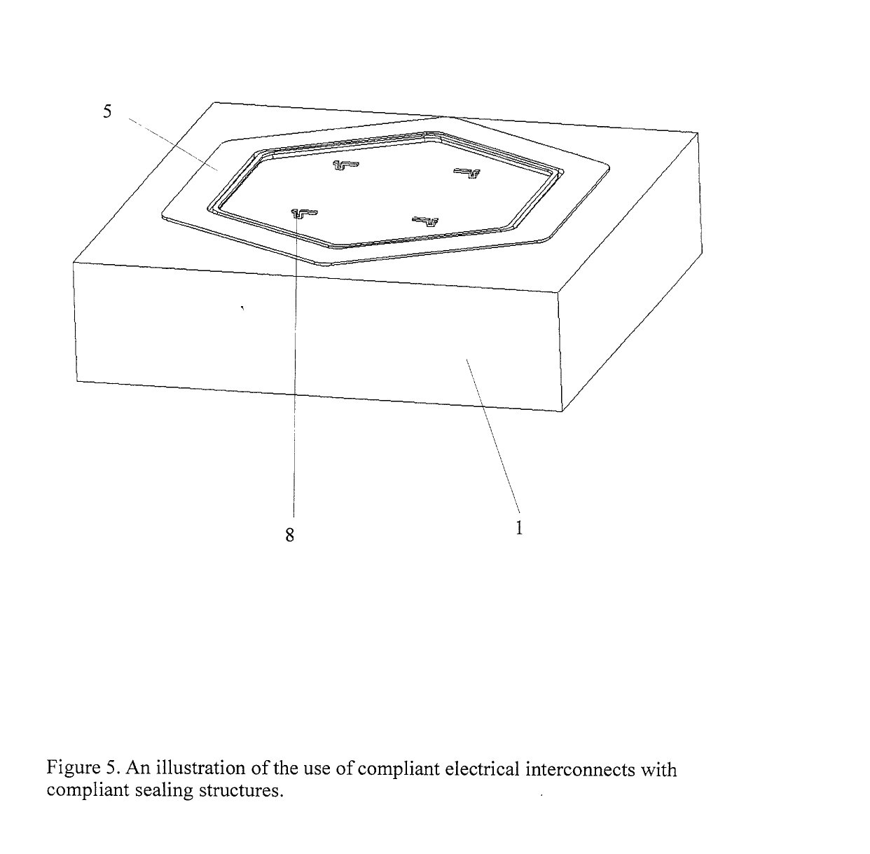

To electrically interconnect the substrates, conductive bumps can be used, but it is preferable to use compliant electrical interconnects. FIG. 5 illustrates the use of compliant electrical interconnects, 8, with a hexagon shaped compliant sealing structure, 5.

Further improvement in seal performance and reliability can be achieved by various means, including but not limited to:

a. Use substrates with more-closely matched coefficient of thermal expansion.

b. Thinning at least some areas of one or more substrates.

c. Make the seals very wide, with lots of corrugations.

d. If hermeticity is not necessary, some or all of the seals can be discontinuous.

In devices which can benefit from electrical interconnects between at least 2 substrates, while conductive bumps can be used for electrical interconnection, it is preferable that compliant electrical interconnects be used. FIG. 5 illustrates the use of compliant electrical interconnects, 8, and hexagon shaped compliant sealing structures, 5. Whether electrical interconnects are compliant or not, it is preferable that interconnects and seals share at least one device layer. It is more preferable that interconnects and seals share substantially all applicable device layers—such that no additional layers are needed. With compliant interconnects where at least one sacrificial layer is removed to free the structural layers of interconnects for movement, it is preferable that interconnects and seals share at least one sacrificial layer. It is more preferable that interconnects and the seals share substantially all applicable sacrificial layers. It is preferable that the compliant interconnects and seals share at least one structural layer. It is more preferable that interconnects and seals share all applicable layers.

Gold bump bonding is the preferred bonding method. Other bonding methods can be used, including but not limited to:

a. gold bump bonding, preferably at temperature of less than 450 degrees C., even more preferably below 353 degrees C., and at pressures of less than 75,000 PSI (more preferably less than 30,000 PSI) over bonding areas, and preferably with surface cleaning to improve bond strength, including but not limited to UV-ozone, sputtering clean, argon plasma, oxygen plasma, hydrogen plasma, sulfuric acid, hydrogen peroxide, or any combination,

b. gold bump bonding at room temperature

c. gold bump bonding near room temperature

d. bonding at room temperature,

e. bonding near room temperature,

f. solder bump bonding,

g. indium bump bonding,

h. polymer bump bonding,

i. bonding with gold on at least one bonding surface,

j. bonding with solder on at least one bonding surface,

k. bonding with indium on at least one bonding surface,

l. bonding with conductive polymer on at least one bonding surface,

m. bonding wherein at least one adhesive provides at least the majority of the bonding strength between said substrates,

n. bonding wherein at least one adhesive provides at least majority of the bonding strength between said substrates, and device hermeticity is improved from structures which assist in sealing including but not limited to structures made of at least one less-gas-permeable material,

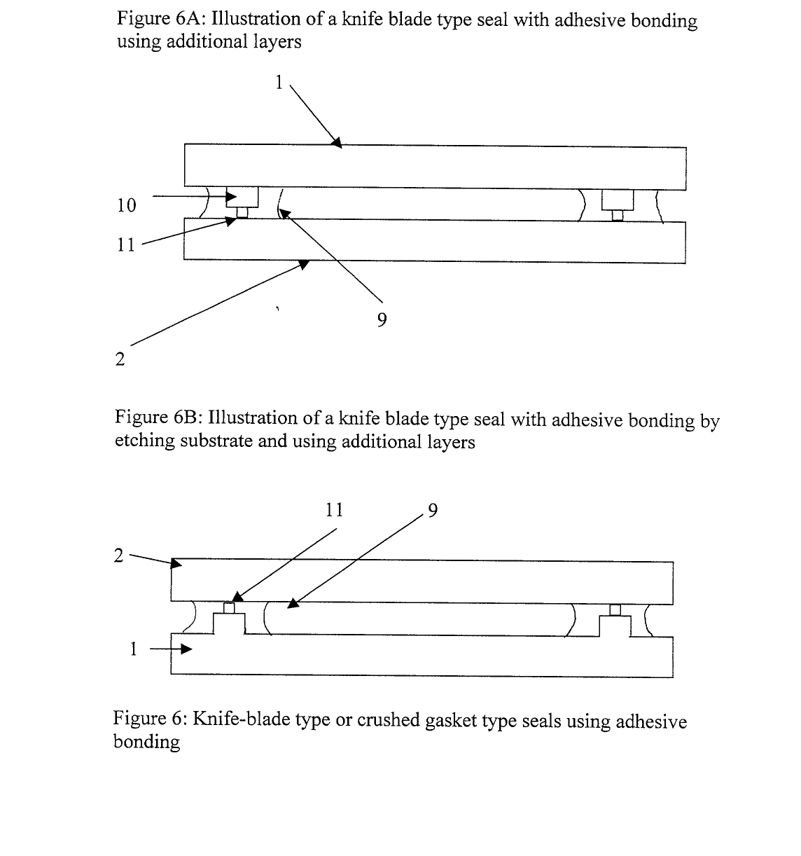

o. bonding wherein at least one adhesive provides at least the majority of the bonding strength between said substrates, and device hermeticity is improved from at least one knife-blade type seal, crush-gasket type seal or a combination made of at least one less-gas-permeable material from deposited layers, substrate, or combination. FIG. 6 illustrates knife-blade type and crush-gasket type seals.

p. bonding wherein at least one adhesive provides at least the majority of the bonding strength between said substrates, and device hermeticity is improved by adding less gas permeable materials into the adhesive or add less permeable materials adjacent to the adhesive by depositing layers on one or more substrates, removing materials from one or more substrates, or any combination,

q. bonding wherein a solder bond provides the majority of the bonding strength between said substrates,

r. bonding wherein a gold thermal compression bond provides the majority of the bonding strength between said substrates,

s. bonding wherein a gold compression bond provides the majority of the bonding strength between said substrates,

t. bonding wherein the majority of the bonding strength between said substrates is provided from a bonding process involving the formation of at least one amalgam,

u. bonding wherein the majority of the bonding strength between said substrates is provided from a cold welding process,

v. any combination including one or more of the above bonding processes.

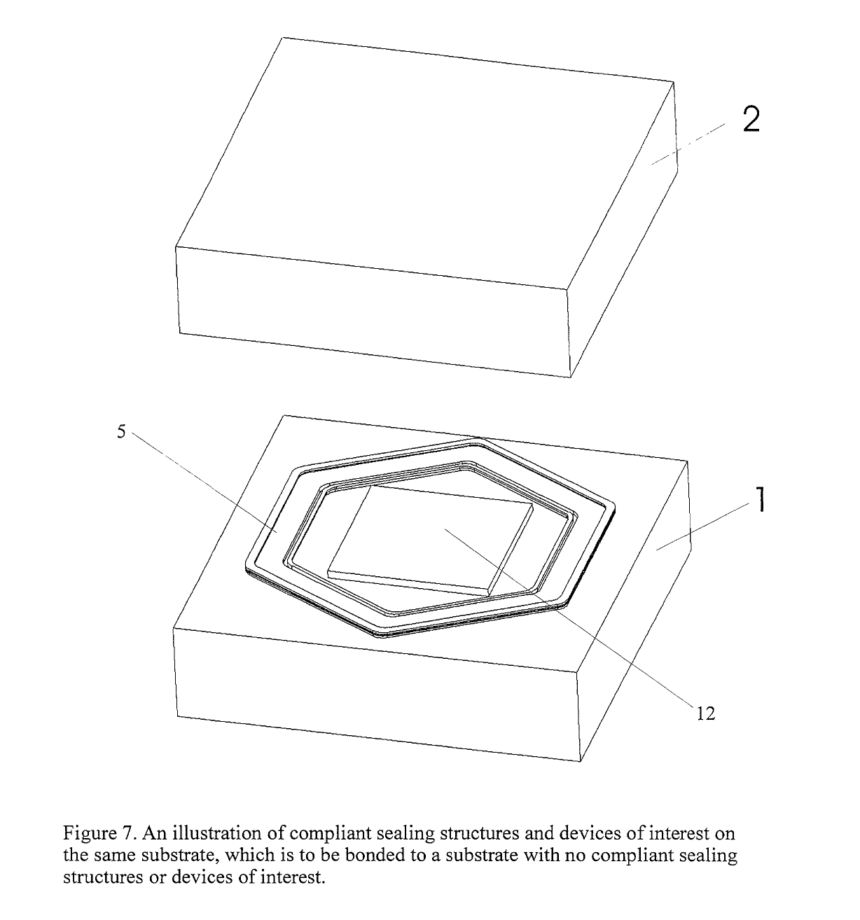

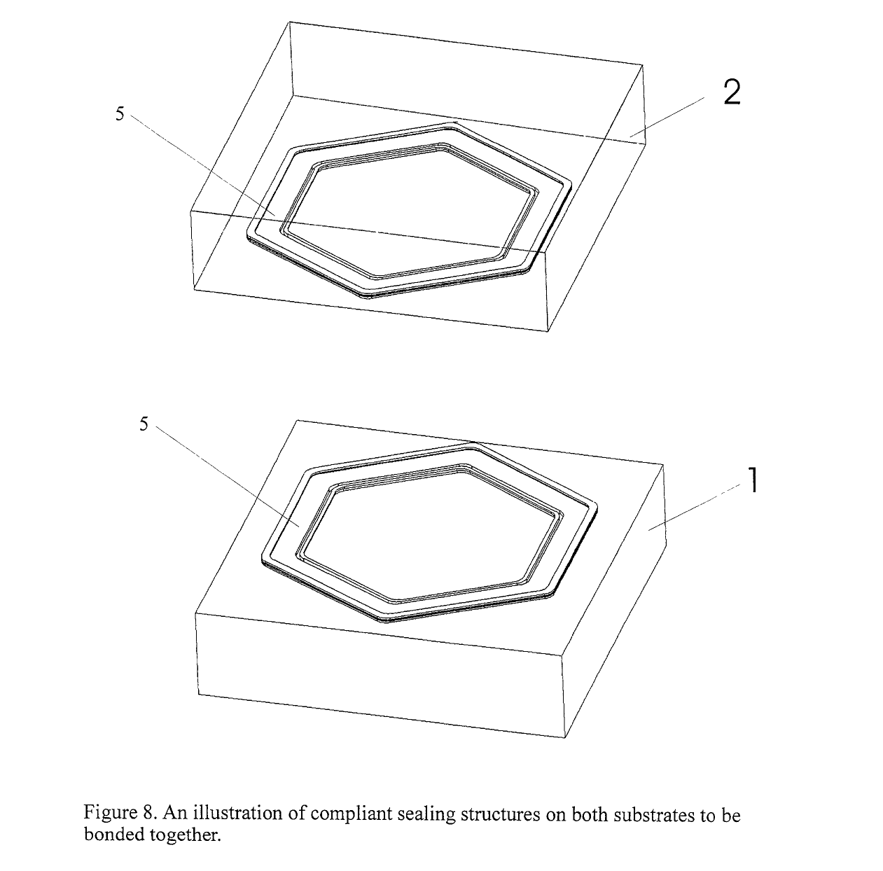

In some cases, it may be preferable to have compliant sealing structures (hexagon shape seals, 5, in this case) on one substrate, 1, for bonding to a second substrate, 2, with the devices of interest, 8. In other cases, it may be preferable to have both the compliant sealing structures and devices of interest, 12, on the same substrate, which is bonded to a substrate, 2, with no compliant sealing structures nor devices of interest. FIG. 7 illustrates this embodiment. In another embodiment, compliant sealing structures (hexagon shape seals, 5, in this case) are on both substrates to be bonded together. FIG. 8 illustrates this embodiment. In another embodiment, devices of interest, 12, are on both substrates, 1 and 2, to be bonded together.

MEMS Embodiments

For packaging devices with at least one MEMS device structure or at least one device structure which will be released for movement by removal of at least a portion of a sacrificial or other layer, it is preferable that at least some of the device structures and compliant sealing structures share at least one sacrificial layer. It is more preferable that all of the device structures and the compliant sealing structures share substantially all of the applicable sacrificial layers. It is preferable that at least some of the device structures and compliant sealing structures share at least one structural layer. It is more preferable that all of the device structures and compliant sealing structures share substantially all of the applicable structural layers. If these device can benefit from electrical interconnects between at least 2 substrates, it is preferable that compliant electrical interconnects be used.

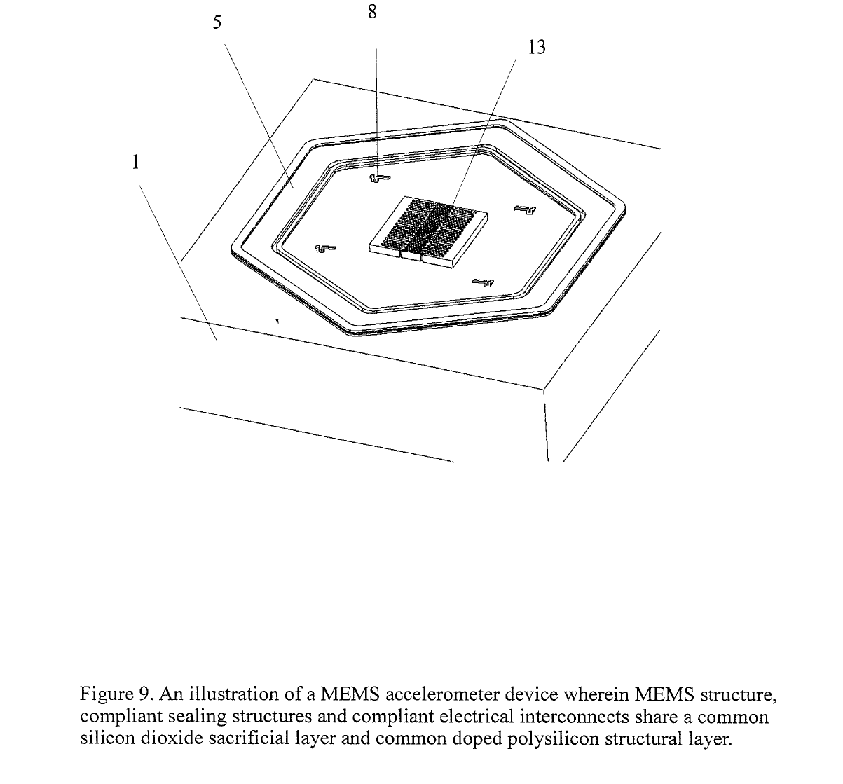

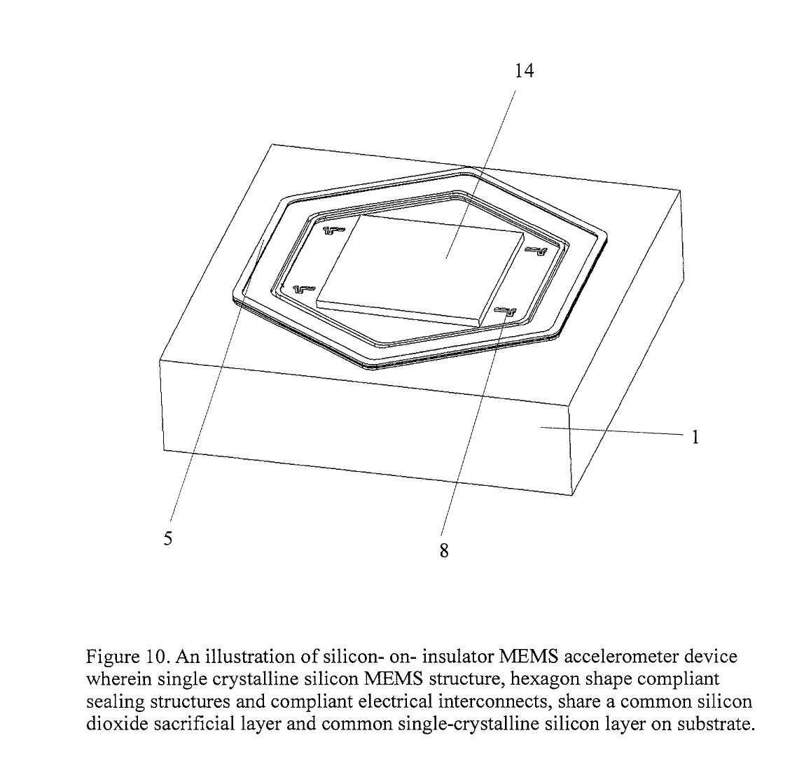

FIG. 9 illustrates a polysilicon MEMS accelerometer device wherein polysilicon MEMS structure, 13, compliant sealing structures (hexagon shape seal, 5, in this case) and compliant electrical interconnects, 8, share a common silicon dioxide sacrificial layer and common doped polysilicon structural layer on seal substrate, 1. FIG. 10 illustrates a silicon-on-insulator MEMS accelerometer device wherein silicon-on-insulator MEMS structure, 14, compliant sealing structures (hexagon shape in this case), 5, and compliant electrical interconnects, 8, share a common silicon dioxide sacrificial layer and common single-crystalline silicon layer on seal substrate, 1.

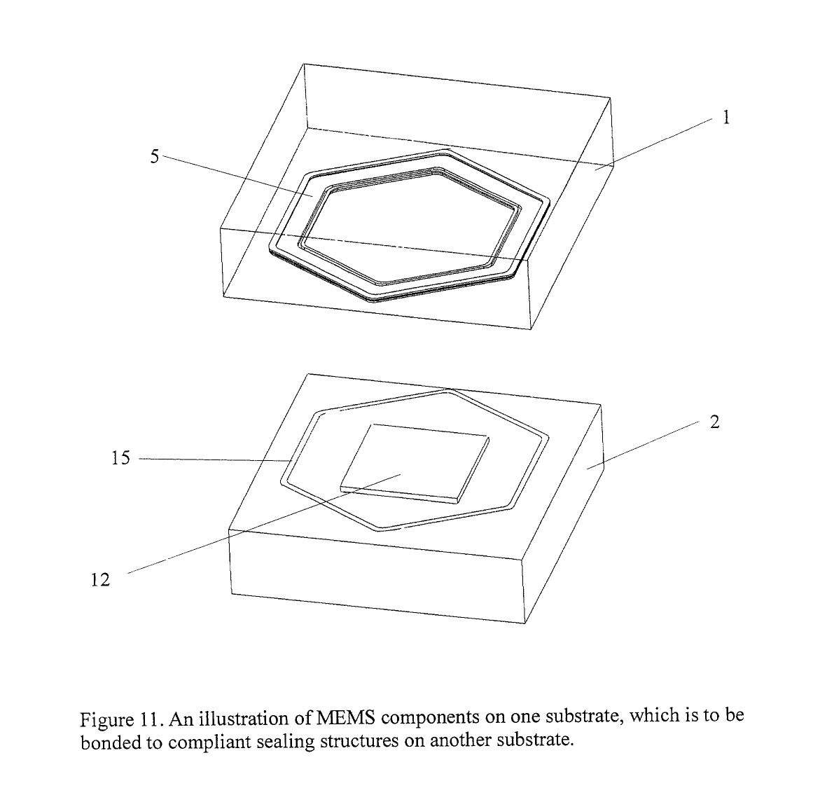

Another embodiment has MEMS components or other device(s) of interest, 12, on one substrate, 2, which is bonded to compliant sealing structures (hexagon shape seals, 5, in this case) on seal substrate, 1. FIG. 11 illustrates this embodiment. Optional metallization, 15, is for certain bonding processes.

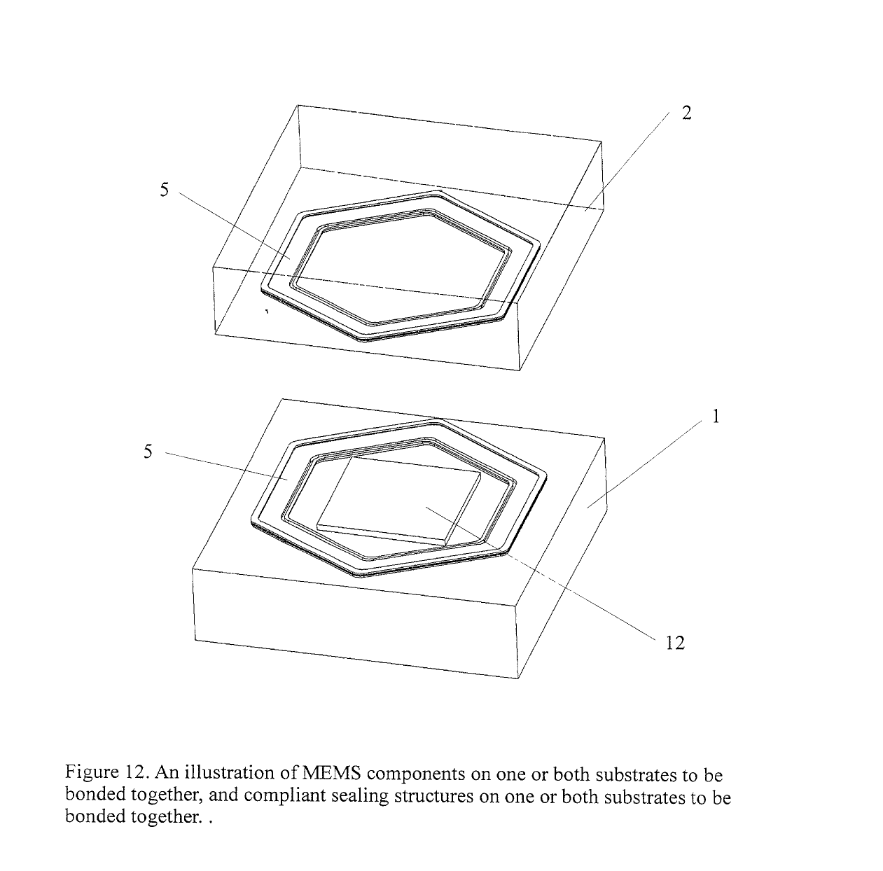

Another embodiment has MEMS components or other device(s) of interest, 12, on one or both substrates to be bonder together (in this case, on one substrate, 1), and compliant sealing structures (hexagon shape seals, 5) on one or both substrates (in this case, on both substrates, 1 and 2) to be bonded together. FIG. 12 illustrates this embodiment.

Fabrication Processes for the Compliant Sealing Structures, Compliant Electrical Connectors or Other MEMS Devices

Typical and standard microfabrication processes can be used to fabricate the compliant sealing structures and compliant electrical connector. Deposition processes include but are not limited to sputtering, evaporation, electroplating, electroless plating, chemical vapor deposition, spin coating, or laser assisted processes. Etching processes include but are not limited to plasma etching, RIE etching, chemical etching, wet etching, ion milling, polishing, chemical mechanical polishing, lapping, or grinding. Photolithography would be the preferable means for patterning the various layers. Surface cleaning means for bonding surfaces include but are not limited to plasma cleaning, argon plasma, oxygen plasma, hydrogen plasma, piranha, sputter clean, UV ozone, hydrofluoric acid, nitric acid, hydrochloric acid, RCA clean, or any combination.

Simple embodiments would have structural and sacrificial layers. Part of if not all of the sacrificial layers are etched away during fabrication. In some cases, it is even possible to use the same material as both structural and sacrificial layer, for example, gold. If a thin layer of gold is deposited on a wafer by evaporation, followed by a plated gold layer, the evaporated layer may be etched more quickly in a wet etchant, because of its porous structure. Thus, it may be undercut.

Bonding Processes

Bonding processes for providing sealing and/or electrical connections that can be used by the current invention include but are not limited to thermal compression bonding, cold welding, solder bump bonding, gold thermal compression bonding, gold-indium, indium bump, gold-tin, eutectic bonding, polymer bump, adhesive bonding, bonding involving the formation of one or more amalgams, or any combination of these processes. It is preferable that the bonding process be performed at near room temperature. It is more preferable that the bonding process be performed at room temperature. Another embodiment would be performing at least some portion of the bonding process at near or room temperatures.

In cases wherein there are fragile bonds, a soft underfill may be used to protect these bonds. The underfill material may be applied to the whole underside of the chip, or selectively, e.g. to the corners or under the center. Other additional means for providing mechanical stability can also be used, including but not limited to thermal compression bonding, cold welding, solder bonding, polymer bump bonding, solder bump bonding, eutectic bonding, adhesive bonding, bonding involving the formation of one or more amalgams, or any combinations of these processes.

In cases where the gap between the substrates is important, spacers can be used to control the gap during and/or after the bonding process. Preferably in these cases, the spacers are fabricated using any, some, or all of the existing device or packaging layers, without adding additional layers.

Gold bump bonding is the preferred bonding method. Preferably, gold bump material or other bump materials described in this disclosure can be patterned in seal rings or other patterns including but not limited to structures for sealing, interconnects, holding at least two substrates together, or any combinations. Optionally, additional materials are deposited prior to deposition of gold bump material or other bump materials for bonding process described to make the total stack taller or higher aspect ratio. Said additional materials that are deposited include but are limited to metals, ceramic, nickel, oxide, nitride, polysilicon, single crystalline silicon, or any combination. For contamination sensitive applications, this is one preferred option. Other bonding methods can be used, including but not limited to:

a. gold bump bonding, preferably at temperature of less than 450 degrees C., even more preferably below 353 degrees C., and at pressures of less than 75,000 PSI (more preferably less than 30,000 PSI) over bonding areas, and preferably with surface cleaning to improve bond strength, including but not limited to UV-ozone, sputtering clean, argon plasma, oxygen plasma, hydrogen plasma, sulfuric acid, hydrogen peroxide, or any combination,

b. gold bump bonding at room temperature,

c. gold bump bonding near room temperature,

d. bonding at room temperature, preferably with surface cleaning to improve bonding strength, including but not limited to UV-ozone, sputtering clean, argon plasma, oxygen plasma, hydrogen plasma, sulfuric acid, hydrogen peroxide, or any combination,

e. bonding near room temperature, preferably with surface cleaning to improve bonding strength, including but not limited to UV-ozone, sputtering clean, argon plasma, oxygen plasma, hydrogen plasma, sulfuric acid, hydrogen peroxide, or any combination,

f. solder bump bonding,

g. indium bump bonding,

h. polymer bump bonding,

i. bonding with gold on at least one bonding surface,

j. bonding with solder on at least one bonding surface,

k. bonding with indium on at least one bonding surface,

l. bonding with conductive polymer on at least one bonding surface,

m. bonding wherein at least one adhesive provides at least the majority of the bonding strength between said substrates,

n. bonding wherein at least one adhesive provides at least majority of the bonding strength between said substrates, and device hermeticity is improved from structures which assist in sealing including but not limited of structures which comprise at least less-gas-permeable material from deposited layers, substrate, or combination including but not limited to silicon oxide, single crystal silicon, polysilicon, silicon nitride, gold, nickel, indium, titanium, tungsten, titanium nitride, solder, other ceramics, other metals, or any combination,

o. bonding wherein at least one adhesive provides at least the majority of the bonding strength between said substrates, and device hermeticity is improved from at least one knife-blade type seal, crush-gasket type seal or a combination which comprises at least one less-gas-permeable material from deposited layers, substrate, or combination including but not limited to silicon oxide, single crystal silicon, polysilicon, silicon nitride, gold, nickel, indium, titanium, tungsten, titanium nitride, solder, other ceramics, other metals, or any combination.

p. bonding wherein at least one adhesive provides at least the majority of the bonding strength between said substrates, and device hermeticity is improved by adding less-gas-permeable materials into the adhesive or adding less-gas-permeable materials adjacent to the adhesive by depositing layers on one or more substrates, removing materials from one or more substrates, or any combination. This may be in various forms, including but not limited to filler materials to reduce adhesive gas permeability, device seal designs to minimize adhesive cross-section for gas permeation.

q. bonding wherein a solder bond provides the majority of the bonding strength between said substrates,

r. bonding wherein a gold thermal compression bond provides the majority of the bonding strength between said substrates,

s. bonding wherein a gold compression bond provides the majority of the bonding strength between said substrates,

t. bonding wherein the majority of the bonding strength between said substrates is provided from a bonding process involving the formation of at least one amalgam,

u. bonding wherein the majority of the bonding strength between said substrates is provided from a cold welding process,

v. any combination including at least one of the above bonding processes.

In most cases, alignment between the various substrates and structures are important. Alignment bonding is generally performed in, but not limited to, the following fashion:

a. Two or more substrates are aligned face-to-face in an arrangement such that the applicable features and/or structures on one substrate are aligned with the corresponding features and/or structures on the other substrate(s).

b. Preferably, the two substrates are then compressed together. If appropriate, heating is applied, so that a bond is formed between the applicable areas of the sealing structures, substrates and other structures.

c. For a cold welding embodiment, heating would not be necessary.

Substrates

The one or more substrates on which the devices are fabricated or interconnected include but are not limited to silicon, glass wafers, printed circuit boards (PCB), multichip module (MCM) substrates, low-parasitic substrates, alumina substrates, glass substrates (including but not limited to pyrex wafers, fused quartz wafers or single crystalline quartz wafers) mention both glass substrates and wafers), insulating substrates, sapphire substrates, silicon substrates, or other semiconductor substrates. The preferable substrate is a silicon substrate, such as a silicon wafer or a silicon-on-insulator substrate.

At least one portion of at least one substrate can be removed after bonding. Means for removing at least one portion include but are not limited to mechanical abrasion, laser, machining, polishing, lapping, grinding, dicing, etching, chemical etching, plasma etching, ion milling, pulling apart, pulling apart at at least one location designed to be mechanically weaker, ion implant combined with other processes, and any combination.

Sacrificial Layers

Sacrificial layers can be layers of various materials, including but not limited to doped silicon oxide, undoped silicon oxide, germanium, aluminum, other metals, polyimide, other polymers, graphite, or any combination of these materials. For devices with compliant seals and compliant interconnects, it is preferable that the seals and interconnects shares at least one sacrificial layer. It is more preferable that the seals and the interconnects substantially share all applicable sacrificial layers. It is preferable that some or all materials above and below etched sacrificial layers would not easily bond to each other when compressed together during follow-on process, particularly the bonding process(es).

For devices with polysilicon or single crystalline silicon as a structural layer, a phosphosilicate glass or undoped glass is preferably deposited, preferably at least 1-2 μm in thickness, or other appropriate thickness to act as a sacrificial layer.

With compliant seal designs wherein multilevel plating processes are used to form more complex 3-D sealing structures, one means for releasing the sealing structures may be performed by etching away the resist mold materials, typically thick Photoresist layers, by processes including but not limited to chemical etching, plasma etching or any combination.

Structural Layers

Structural layers of the compliant seals and interconnects can be one or more layers of various materials including but not limited to polysilicon, silicon carbide, single crystalline silicon, silicon-germanium, gold, noble metals, barrier metals, other semiconductor, nickel, other metals, alloys, silicon oxide, silicon oxynitride, other ceramics, polymer, alumina, or any combination of these materials. The preferable materials are polysilicon and gold. The deposition processes and etching processes for forming the structural layers are listed in the Fabrication Processes section. For devices with compliant seals and compliant interconnects, it is preferable that the seals and interconnects shares at least one structural layer. It is more preferable that the seals and the interconnects substantially share all applicable structural layers.

Process Flow for Sealing Structures on MEMS Substrate Sharing Sacrificial Layers and Structural Layers with MEMS Device

There are substantial advantages to having compliant sealing structures on the MEMS substrates. One important advantage is the potential to share device layers for the MEMS devices and the compliant seal structures. The following process flows are preferable embodiments for polysilicon MEMS and silicon-on-insulator (single crystalline) MEMS.

Polysilicon MEMS process flows:

a. Deposit at least 2 microns of doped, undoped or a combination silicon oxide layer on bare silicon wafer substrate by chemical vapor deposition.

b. Deposit at least 2 microns of doped polysilicon structural layer by chemical vapor deposition, and anneal the wafer at high temperatures (such as 1000° C.) to remove stress.

c. Optionally, silicon nitride layer is deposited by chemical vapor deposition, coat and pattern photoresist layer, etch silicon nitride layer preferably by dry etch process, and remove photoresist layer by standard dry or wet processes.

d. Coat and pattern photoresist layer.

e. Etch polysilicon layer preferably by dry etch process.

f. Remove photoresist layer using standard wet or dry processes.

g. Deposit metal layer, preferably by sputtering, preferably titanium tungsten (TiW) layer. Other metal layers that can be deposited include but are not limited to: titanium nitride, titanium, tantalum, tantalum nitride, chromium, gold, metal silicides, platinum, nickel, other metals, alloys of these materials, or any combination of these materials. Coat and pattern photoresist layer. Etch said metal layer to obtain features of appropriate size(s).

h. Optionally, deposit one or more additional metal layer(s), preferably deposited by sputtering. A gold layer is preferred. Other metal layers that can be deposited include but are not limited to: titanium tungsten, platinum, titanium, titanium nitride, titanium tungsten, nickel, copper, metal silicides, other metals, alloys of these materials, or any combination of these materials. Coat and pattern photoresist layer. Etch said metal layer to obtain features of appropriate size(s). Optionally, repeat this step as applicable.

i. Optionally, coat and pattern photoresist layer to serve as an electroplating mold for one or more additional metal layer(s), preferably deposited by electroplating. A gold layer is preferred. Other metal layers that can be deposited include but are not limited to: titanium tungsten, platinum, titanium, titanium nitride, titanium tungsten, nickel, copper, metal silicides, other metals, alloys of these materials, or any combination of these materials. Optionally etch away resist mold after each plate step. Optionally, repeat this process as applicable. Optionally, etch photoresist mold by various means, including but not limited to dry etching, wet processing or any combination.

j. Optionally, coat substrate with coatings to protect surface films from the next step, using materials including but not limited to chrome films, photoresist, or any combination

k. Partially etch the bottom undoped silicon oxide layer to release MEMS structures, sealing structures and interconnect structures by wet etching or other etchants, including but not limited to hydrofluoric acid, diluted hydrofluoric acid, anhydrous hydrofluoric acid, or any combination.

Or

a. Deposit at least 2 microns of undoped silicon oxide layer on bare silicon wafer substrate by chemical vapor deposition.

b. Deposit at least 2 microns of doped polysilicon structural layer by chemical vapor deposition, and anneal the wafer at high temperatures (such as 1000° C.) to remove stress.

c. Optionally, silicon nitride layer is deposited by chemical vapor deposition, coat and pattern photoresist layer, etch silicon nitride layer preferably by dry etch process, and remove photoresist layer by standard dry or wet processes.

d. Deposit metal layer, preferably by sputtering, preferably titanium tungsten (TiW) layer. Other metal layers that can be deposited include but are not limited to: titanium nitride, titanium, tantalum, tantalum nitride, chromium, gold, metal silicides, platinum, nickel, other metals, alloys of these materials, or any combination of these materials. Coat and pattern photoresist layer. Etch said metal layer to obtain features of appropriate size(s).

e. Optionally, deposit one or more additional metal layer(s), preferably deposited by sputtering. A gold layer is preferred. Other metal layers that can be deposited include but are not limited to: titanium tungsten, platinum, titanium, titanium nitride, titanium tungsten, nickel, copper, metal silicides, other metals, alloys of these materials, or any combination of these materials. Coat and pattern photoresist layer. Etch said metal layer to obtain features of appropriate size(s). Optionally, repeat this step as applicable.

f. Optionally, coat and pattern photoresist layer to serve as an electroplating mold for one or more additional metal layer(s), preferably deposited by electroplating. A gold layer is preferred. Other metal layers that can be deposited include but are not limited to: titanium tungsten, platinum, titanium, titanium nitride, titanium tungsten, nickel, copper, metal suicides, other metals, alloys of these materials, or any combination of these materials. Optionally etch away resist mold after each plate step. Optionally, repeat this process as applicable. Optionally, etch photoresist mold by various means, including but not limited to dry etching, wet processing or any combination.

g. Coat and pattern photoresist layer.

h. Etch polysilicon layer preferably by dry etch process.

i. Remove photoresist layer using standard wet or dry processes.

j. Optionally, coat substrate with coatings to protect surface films from the next step, using materials including but not limited to chrome films, photoresist, or any combination

k. Partially etch the bottom undoped silicon oxide layer to release the MEMS structures, seal structures and other structures by wet etching or other etchants, including but not limited to hydrofluoric acid, diluted hydrofluoric acid, anhydrous hydrofluroic acid, or any combination.

Single Crystalline MEMS process flow:

a. Start with silicon on insulator (SOI) wafer, preferably with at least 2 microns of undoped or undoped silicon oxide layer, and a thick single crystalline silicon layer, preferably at least 20 microns thick.

b. Optionally, silicon nitride layer is deposited by chemical vapor deposition, coat and pattern photoresist layer, etch silicon nitride layer preferably by dry etch process, and remove photoresist layer.

c. Coat and pattern photoresist layer as mask layer or use photoresist to pattern masking layers such as metals or oxide.

d. Etch top silicon layer preferably by dry etch process, preferably using DRIE processes.

e. Remove photoresist layer or other masking layers using standard wet or dry processes.

f. Deposit metal layer, preferably by sputtering, preferably titanium tungsten (TiW) layer. Other metal layers that can be deposited include but are not limited to: titanium nitride, titanium, tantalum, tantalum nitride, chromium, gold, metal silicides, platinum, nickel, other metals, alloys of these materials, or any combination of these materials. Coat and pattern photoresist layer. Etch said metal layer to obtain features of appropriate size(s).

g. Optionally, deposit one or more additional metal layer(s), preferably deposited by sputtering. A gold layer is preferred. Other metal layers that can be deposited include but are not limited to: titanium tungsten, platinum, titanium, titanium nitride, titanium tungsten, nickel, copper, metal silicides, other metals, alloys of these materials, or any combination of these materials. Coat and pattern photoresist layer. Etch said metal layer to obtain features of appropriate size(s). Optionally, repeat this step as applicable.

h. Optionally, coat and pattern photoresist layer to serve as an electroplating mold for one or more additional metal layer(s), preferably deposited by electroplating. A gold layer is preferred. Other metal layers that can be deposited include but are not limited to: titanium tungsten, platinum, titanium, titanium nitride, titanium tungsten, nickel, copper, metal silicides, other metals, alloys of these materials, or any combination of these materials. Optionally etch away resist mold after each plate step. Optionally, repeat this process as applicable. Optionally, etch photoresist mold by various means, including but not limited to dry etching, wet processing or any combination.

i. Optionally, coat substrate with coatings to protect surface films from the next step, using materials including but not limited to chrome films, photoresist, or any combination

j. Partially etch the bottom silicon oxide layer of SOI substrate to release the MEMS structures, compliant seal structures or other structures, by wet etching or other etchants, including but not limited to hydrofluoric acid, diluted hydrofluoric acid, anhydrous hydrofluroic acid, or any combination.

Or:

a. Start with silicon on insulator (SOI) wafer, preferably with at least 2 microns of oxide layer, and a thick single crystalline silicon layer, preferably at least 20 microns thick.

b. Optionally, silicon nitride layer is deposited by chemical vapor deposition, coat and pattern photoresist layer, etch silicon nitride layer preferably by dry etch process, and remove photoresist layer by standard wet or dry processes.

c. Deposit metal layer, preferably by sputtering, preferably titanium tungsten (TiW) layer. Other metal layers that can be deposited include but are not limited to: titanium nitride, titanium, tantalum, tantalum nitride, chromium, gold, metal silicides, platinum, nickel, other metals, alloys of these materials, or any combination of these materials. Optionally, coat and pattern photoresist layer, and etch said metal layer to obtain features of appropriate size(s).

d. Optionally, deposit one or more additional metal layer(s), preferably deposited by sputtering. A gold layer is preferred. Other metal layers that can be deposited include but are not limited to: titanium tungsten, platinum, titanium, titanium nitride, titanium tungsten, nickel, copper, metal suicides, other metals, alloys of these materials, or any combination of these materials. Coat and pattern photoresist layer. Etch said metal layer to obtain features of appropriate size(s). Optionally, repeat this step as applicable. If plating is used, then a photoresist mold would be have be formed prior to plating, and removed after plating.

e. Optionally, coat and pattern photoresist layer to serve as an electroplating mold for one or more additional metal layer(s), preferably deposited by electroplating. A gold layer is preferred. Other metal layers that can be deposited include but are not limited to: titanium tungsten, platinum, titanium, titanium nitride, titanium tungsten, nickel, copper, metal silicides, other metals, alloys of these materials, or any combination of these materials. Optionally etch away resist mold after each plate step. Optionally, repeat this process as applicable. Optionally, etch photoresist mold by various means, including but not limited to dry etching, wet processing or any combination.

f. Optionally, coat substrate with coatings to protect surface films from the next step, using materials including but not limited to chrome films, photoresist, or any combination,

g. Coat and pattern photoresist layer as mask layer or use photoresist to pattern masking layers such as metals or oxide.

h. Etch top silicon layer preferably by dry etch process, preferably using DRIE processes.

i. Remove photoresist layer or other masking layers using standard wet or dry processes.

j. Optionally, coat substrate with coatings to protect surface films from the next step, using materials including but not limited to chrome films, photoresist, or any combination

k. Partially etch the bottom silicon oxide layer to release the MEMS structures, seal structures and other structures, by wet etching or other etchants, including but not limited to hydrofluoric acid, diluted hydrofluoric acid, anhydrous hydrofluroic acid, or any combination.

Process Flow for Sealing Structures on Lid

There are substantial advantages in providing compliant sealing structures on the packaging lid with few or no MEMS devices (or other devices). This simplifies the business model for a contract packaging business—customers only have to supply their devices on wafers or other substrates—the packaging contractor would supply necessary features to package the devices, including compliant seals, compliant or other interconnects, packaging substrate(s), or any combination. For certain metal-to-metal bonding processes, it is preferable to have certain metals not the substrate to be packaged, including but not limited to gold, metals with no or minimal surface oxides, or alternatively, surface cleaning is preferable to remove contamination including but not limited to surface oxides or hydrocarbons. Surface cleaning means for bonding surfaces include but are not limited to plasma cleaning, argon plasma, oxygen plasma, hydrogen plasma, piranha, sputter clean, UV ozone, hydrofluoric acid, nitric acid, hydrochloric acid, RCA clean, or any combination. The following is a preferable embodiment.

Process flow for fabrication of lid with compliant sealing structures and compliant electrical interconnects:

a. Start with silicon dioxide substrate (including but not limited to pyrex wafers, fused quartz wafers, single crystalline quartz wafers), alumina substrate, sapphire substrate, or silicon wafer (high resistivity silicon may be preferred for RF performance if important).

b. Optionally, deposit a silicon oxide layer, preferably at least 1 micron thick, by chemical vapor deposition.

c. Deposit metal layer, preferably by sputtering, preferably at least 400 angstroms of titanium tungsten (TiW), at least 200 angstroms of gold and at least 400 angstroms of TiW. Even more preferably, deposit by sputtering at least 1000 angstroms of TiW, at least 1 micron of gold and at least 1000 angstroms of TiW. Other metal layers that can be deposited include but are not limited to: titanium nitride, titanium, tantalum, tantalum nitride, chromium, metal silicides, platinum, nickel, other metals, alloys of these materials, or any combination of these materials,

d. Optionally, deposit additional metal layer, preferably deposited by sputtering. Metal layers that can be deposited include but are not limited to: gold, titanium tungsten, platinum, titanium, titanium nitride, titanium tungsten, nickel, copper, metal silicides, other metals, alloys of these materials, or any combination of these materials. If plating is used, then a photoresist mold would be have be formed prior to plating, and removed after plating.

e. Optionally, particularly if plating is not used, coat and pattern photoresist layer.

f. Optionally, particularly if plating is not use, perform partial etch of metal layers beneath, preferably with dry etch, wet etch, sputter etch, or a combination, preferably to clear metallization from masked areas, without severely undercutting masked areas.

g. Deposit electrical insulating layer, preferably by chemical vapor deposition. Low temperature oxide is preferred, preferably at a deposition temperature below 550° C., even more preferably below 460° C.

h. Coat and pattern photoresist layer.

i. Etch insulating layer preferably by dry etch process.

j. Remove photoresist layer using standard wet or dry processes.

k. Coat and pattern photoresist layer for electroplating mold.

l. Deposit metal bumps and features, preferably by electroplating, preferably gold bumps and features at least 2 microns thick, even more preferably, gold bumps and features at least 5 microns thick.

m. Remove photoresist layer using standard wet or dry processes.

n. Optionally, perform a partial etch of the deposited metal layers, preferably by wet etching, dry etching, sputter etch or a combination.

o. Optionally, metal bumps can be annealed.

Process Flow for Adhesive Based Sealing with Additional Features Supplying Hermeticity

FIG. 6 illustrates a knife-blade type seal. Adhesive based bonding is useful as it eliminates requirements of certain other bonding techniques that may have metallization requirements for substrates to be bonded. For example, one substrate to be bonded would have all of the needed features for compliant sealing, including adhesives, interconnects, and features for improving hermeticity. In some cases, adhesive bonding provides adequate compliant bonding, and improved hermeticity is supplied by other features which comprise at least one material with lower-gas-permeability. With adhesives providing substantial bonding force, the other materials or structures do not have to be designed for compliancy, as they do not have to be directly bonded to supply additional bonding force. These materials may preferably be used in a crush-gasket type seal or knife-blade type seal. Materials with lower-gas-permeability include but are not limited to metals, ceramics, dielectrics, gold, nickel, titanium, tungsten, titanium nitride, silicon oxide, silicon nitride, parts of substrates, silicon, polysilicon, semiconductor, indium, solder, aluminum, copper, or any combinations. These materials may be deposited by processes described in the process section, including but not limited to sputtering, electroplating, electroless plating, evaporation, vapor deposition, CVD, spin-on, or any combination. Some or all of the features with low-gas-permeability can be etched from one or more substrates.

When substrates are compressed together, preferably, sufficiently combination of pressure and/or heating could applied to deform the sealing elements together to reduce adhesive cross-section for minimizing gas permeability. Materials which would deform with less pressure/temperature include but are not limited to gold, indium, solder, or any combination. Preferably, compliant sealing structures and adhesives are deposited on the packaging lid with few or no MEMS devices (or other devices). This simplifies the business model for a contract packaging business—customers only have to supply their devices on wafers or other substrates—the packaging contractor would supply necessary features to package the devices, including compliant seals, compliant or other interconnects, packaging substrate(s), or any combination. A preferred embodiment:

a. Fabricate lid substrate as discussed in the embodiment listed under Sealing Structures on Lid section.

b. Apply at least one adhesive to at least one substrate to be bonded, preferably to the lid substrate. Optionally, adhesive is applied to the crush-gasket or knife-blade seal structures. Adhesives can be applied by conventional means, including but not limited to spin-on, serial dispense, stamping, rolling, screen-printing, spraying, or a combination.

c. Align substrates and compress. Optionally, sufficient combination of pressure and temperature is applied to deform some features of the substrates to reduce gas-permeability. Optionally, sufficient combination of pressure and temperature is applied to deform some features of the substrates to provide a hermetic or vacuum seal.

What is claimed is:

1. A device with at least two substrates, wherein at least two substrates are mechanically attached to at least one compliant structure.

2. A device as in claim 1, wherein at least one of said at least two substrates is selected from the following list: silicon wafer with at least one MEMS device, silicon substrate with at least one MEMS device, silicon wafer with at least one semiconductor device, silicon substrate with at least one semiconductor device, III-V semiconductor wafer with at least one optoelectronic device, III-V semiconductor substrate with at least one optoelectronic device, III-V semiconductor substrate with at least one semiconductor device, III-V semiconductor substrate with at least one MEMS device, low parasitic substrate, or low loss substrate.

3. A device as in claim 1 wherein said at least one compliant structure seals together at least one location between said at least two substrates.

4. A device as in claim 1 wherein at least one portion of at least one of said at least two substrates is removed after sealing.

5. A device as in claim 3 wherein said at least one compliant structure provides a seal of the type selected from the follow list: hermetic seal, vacuum seal, or gross-leak seal.

6. A device as in claim 1 wherein said at least two substrates are electrically interconnected together.

7. A device as in claim 6 wherein said at least two substrates are electrically interconnected with compliant structures.

8. A device with at least two substrates, wherein at least two substrates are mechanically attached to at least one compliant structure, wherein said at least two substrates are bonded to each other with a bonding technique selected from the following list:
a. gold bump bonding,
b. gold bump bonding at room temperature
c. gold bump bonding near room temperature
d. bonding at room temperature
e. bonding near room temperature
f. solder bump bonding,
g. indium bump bonding,
h. polymer bump bonding,
i. bonding with gold on at least one bonding surface,
j. bonding with solder on at least one bonding surface,
k. bonding with indium on at least one bonding surface,
l. bonding with conductive polymer on at least one bonding surface,
m. bonding wherein at least one adhesive provides at least the majority of the bonding strength between said substrates,
n. bonding wherein at least one adhesive provides at least majority of the bonding strength between said substrates, and device herneticity is improved from structures which assist in sealing including but not limited of structures which comprises at least one less-gas-permeable material from deposited layers, substrate, or combination including but not limited to silicon oxide, single crystal silicon, polysilicon, silicon nitride, gold, nickel, indium, titanium, tungsten, titanium nitride, solder, other ceramics, other metals, or any combination,
o. bonding wherein at least one adhesive provides at least the majority of the bonding strength between said substrates, and device hermeticity is improved from at least one knife-blade type seal, crush-gasket type seal or a combination which comprises at least one less-gas-permeable material from deposited layers, substrate, or combination including but not limited to silicon oxide, single crystal silicon, polysilicon, silicon nitride, gold, nickel, indium, titanium, tungsten, titanium nitride, solder, other ceramics, other metals, or any combination,
p. bonding wherein at least one adhesive provides at least the majority of the bonding strength between said substrates, and device hermeticity is improved by adding at least one less gas permeable material into the adhesive or add at least one less-gas-permeable material adjacent to the adhesive by depositing layers on one or more substrates, removing materials from one or more substrates, or any combination,
q. bonding wherein a solder bond provides the majority of the bonding strength between said substrates,
r. bonding wherein a gold thermal compression bond provides the majority of the bonding strength between said substrates,
s. bonding wherein a gold compression bond provides the majority of the bonding strength between said substrates,
t. bonding wherein the majority of the bonding strength between said substrates is provided from a bonding process involving the formation of at least one amalgam,
u. bonding wherein the majority of the bonding strength between said substrates is provided from a cold welding process,
w. any combination including at least one of the above bonding processes.

9. A device as in claim 8 wherein said at least two substrates are bonded to form at least two of said device.

10. A device as in claim 9 wherein said at least two substrates are wafers of approximately the same size.

11. A device as in claim 8 wherein at least one portion of at least one of said at least two substrates is removed after bonding.

12. A device as in claim 8 wherein said bonding process seals said at least two substrates together by at least one compliant seal ring.

13. A device as in claim 8 wherein said bonding process provides a seal of the type selected from the follow list: hermetic seal, vacuum seal, or gross-leak seal.

14. A device as in claim 8 wherein said bonding process also provides at least one electrical interconnect between said at least two substrates.

15. A device as in claim 14 wherein said at least one of said at least one electrical interconnect is a compliant electrical interconnect structure.

16. A device as in claim 15 wherein said at least one compliant seal ring is fabricated using at least one of the device layers of said at least one electrical interconnect structure.

17. A device as in claim 15 wherein said at least one complaint seal ring is fabricated using substantially the same device layers of said at least electrical interconnect structure.

18. A method of assembly of at least two substrates with at least one compliant structure, wherein said at least one compliant structure seals at least one location between at least two substrates.

19. A method as in claim 18 wherein said at least one compliant structure seals at least one location between at least two substrates with a seal of the type selected from the following list: hermetic seal, vacuum seal, or gross-leak seal.

20. A method as in claim 19 wherein at least two substrates are electrically interconnected with a least one electrical interconnect structure.

21. A method as in claim 20 wherein said at least one compliant structure which seals at least one location between said at least two substrates and said at least one electrical interconnect structure share at least one device layer.

22. A method as in claim 21 wherein said at least two substrates are wafers of approximately the same size.

23. A method as in claim 20 wherein at least one portion of at least one of said at least two substrates is removed after sealing.
